(19) United States
(12) Patent Application Publication
(10) Pub. No.: US 2026/0143613 A1
(43) Pub. Date: May 21, 2026

(54) CIRCUIT BOARD MOUNTING STRUCTURE, CIRCUIT BOARD, LIGHTING APPARATUS AND MOTOR VEHICLE

(71) Applicant: VALEO VISION, Bobigny (FR)

(72) Inventors: Yilin LI, Wuhan (CN); Lei ZHU, Wuhan (CN); Yan SUN, Wuhan (CN); Shuang XIAO, Wuhan (CN)

(73) Assignee: VALEO VISION, Bobigny (FR)

(21) Appl. No.: 18/705,789

(22) PCT Filed: Oct. 26, 2022
(86) PCT No.: PCT/EP2022/080019

§ 371 Date: Apr. 29, 2024

(30) Foreign Application Priority Data
Oct. 28, 2021 (CN) 202122620090.2

(51) Int. Cl. H05K 7/14

(52) U.S. Cl. CPC H05K 7/1405; H05K 7/1417

(57) ABSTRACT

The present invention provides a circuit board mounting structure, including a fixing support and a PCB clamped to the fixing support. A first part of the PCB experiences elastic deformation, and a resulting elastic force clamps the PCB on the fixing support. Because the elastic part is provided on the PCB, the elastic part being capable of experiencing elastic deformation to clamp the PCB on the fixing support, it is possible to avoid the technical problem in the prior art that injection molding is difficult when the elastic part is arranged on the fixing support, and thereby reduce production costs. The present invention further provides a PCB, a lighting apparatus and a motor vehicle.

### TECHNICAL FIELD

The present invention relates to the technical field of vehicle lamps, in particular to a circuit board mounting structure, a circuit board, a lighting apparatus and a motor vehicle.

### BACKGROUND OF THE INVENTION

In the prior art, printed circuit boards (PCBs) are generally fitted to their fixing supports by screw connection or snap-fit connection, etc., compared with screw connection, snap-fit connection has advantages such as low cost and a low likelihood of causing circuit board warpage. Generally, the elastic part of the snap-fit connector is integrally formed with the fixing support by an injection molding process. If the fixing support has a relatively complex structure, then the elastic part of the snap-fit connector and the remainder of the fixing support might need to be demolded in different directions, therefore demolding needs to be performed with the aid of a slider. However, if it is not possible to reserve enough space for the slider, such a technical solution introduces a high degree of technical difficulty to the production process.

### SUMMARY OF THE INVENTION

Thus, an object of the present invention is to propose a circuit board mounting structure, a printed circuit board, a lighting apparatus and a motor vehicle, which can at least partially solve the problems mentioned above.

According to one aspect of the present invention, a circuit board mounting structure is provided, comprising a fixing support and a printed circuit board clamped to the fixing support; a first part of the printed circuit board is capable of generating elastic deformation, and a resulting elastic force clamps the printed circuit board on the fixing support.

According to the embodiments of the present invention, because the elastic part is provided on the printed circuit board, the elastic part being capable of experiencing elastic deformation to clamp the printed circuit board on the fixing support, it is possible to avoid the technical problem in the prior art that injection molding is difficult when the elastic part is arranged on the fixing support, and thereby reduce production costs.

In some embodiments, the printed circuit board further comprises a second part, the second part being clamped to the fixing support, such that the first part experiences elastic deformation relative to the second part under the action of the fixing support.

In some embodiments, the printed circuit board further comprises a second part, the second part being clamped to the fixing support, such that the first part experiences elastic deformation relative to the second part under the action of the fixing support.

In some embodiments, the fixing support comprises at least one fork-shaped part, and the second part is clamped by the fork-shaped part in a mounting direction of the fixing support and the printed circuit board.

In some embodiments, the fixing support further comprises at least one guide rib, for guiding the first part to slide in the mounting direction, and supporting the first part in a direction transverse to the mounting direction, such that the first part experiences elastic deformation.

In some embodiments, the first part protrudes and extends from the second part, such that the printed circuit board forms a T-shaped board.

In some embodiments, the second part comprises at least one guide slot, and the fixing support comprises at least one guide wall, the guide wall being slidable in the guide slot in the opposite direction to a mounting direction of the printed circuit board.

According to the embodiments of the present invention, the guide slot enables the printed circuit board to be fitted to the fixing support more easily.

In some embodiments, a connection region of the first part and the second part comprises a chamfer region. This reduces the stress that arises when the first part experiences elastic deformation relative to the second part, preventing rupture of the connection region.

In some embodiments, electronic components are excluded from the first part, to prevent open circuits due to rupture of an electrically conductive layer when the first part experiences elastic deformation.

In some embodiments, the first part further comprises a first snap-fit part, and the fixing support further comprises a second snap-fit part, the first snap-fit part being snap-fitted to the second snap-fit part. By additionally providing a snap-fit connection, the strength of connection between the printed circuit board and the fixing support can be increased.

In some embodiments, an anti-detachment part is provided on at least one of the first snap-fit part and the second snap-fit part, to prevent the first snap-fit part and second snap-fit part from detaching from each other.

In some embodiments, the first snap-fit part comprises a through-hole, the second snap-fit part comprises a protrusion, and the through-hole is fitted over the protrusion by deformation.

In some embodiments, the first snap-fit part comprises a V-shaped part formed at an extremity of the first part, the second snap-fit part comprises a through-hole, the V-shaped part is inserted in the through-hole by deformation, and the anti-detachment part is formed on the V-shaped part.

In some embodiments, the first snap-fit part comprises a T-shaped part formed at an extremity of the first part, the second snap-fit part comprises a through-hole and two ribs extending in opposite directions in the through-hole, and the T-shaped part passes through the through-hole while twisting under the guiding action of the two ribs and forms an anti-detachment part.

According to another aspect of the present invention, a printed circuit board capable of being clamped to the fixing support is further provided; a first part of the printed circuit board can experience elastic deformation, and a resulting elastic force clamps the printed circuit board on the fixing support.

In some embodiments, the printed circuit board further comprises a second part, the second part being clamped to the fixing support, such that the first part experiences elastic deformation relative to the second part under the action of the fixing support.

In some embodiments, the fixing support comprises at least one fork-shaped part, and the second part is clamped by the fork-shaped part in a mounting direction of the fixing support and the printed circuit board.

In some embodiments, the fixing support further comprises at least one guide rib, for guiding the first part to slide in the mounting direction, and supporting the first part in a direction transverse to the mounting direction, such that the first part experiences elastic deformation.

In some embodiments, the first part protrudes and extends from the second part, such that the printed circuit board forms a T-shaped board.

In some embodiments, the second part comprises at least one guide slot, and the fixing support comprises at least one guide wall, the guide wall being slidable in the guide slot in the opposite direction to a mounting direction of the printed circuit board.

In some embodiments, a connection region of the first part and the second part comprises a chamfer region.

In some embodiments, electronic components are excluded from the first part.

In some embodiments, the first part further comprises a first snap-fit part, and the fixing support further comprises a second snap-fit part, the first snap-fit part being snap-fitted to the second snap-fit part.

In some embodiments, an anti-detachment part is provided on at least one of the first snap-fit part and the second snap-fit part.

In some embodiments, the first snap-fit part comprises a through-hole, the second snap-fit part comprises a protrusion, and the through-hole is fitted over the protrusion by deformation.

In some embodiments, the first snap-fit part comprises a V-shaped part formed at an extremity of the first part, the second snap-fit part comprises a through-hole, the V-shaped part is inserted in the through-hole by deformation, and the anti-detachment part is formed on the V-shaped part.

In some embodiments, the first snap-fit part comprises a T-shaped part formed at an extremity of the first part, the second snap-fit part comprises a through-hole and two ribs extending in opposite directions in the through-hole, and the T-shaped part passes through the through-hole while twisting under the guiding action of the two ribs and forms an anti-detachment part.

According to another aspect of the present invention, a lighting apparatus is further provided, comprising any one of the circuit board mounting structures or any one of the printed circuit boards described above.

According to another aspect of the present invention, a motor vehicle is further provided, comprising the lighting apparatus described above.

### BRIEF DESCRIPTION OF DRAWINGS

To facilitate understanding of the present invention, the present invention is described in greater detail below, based on exemplary embodiments and referring to the drawings. In the drawings, identical or similar reference labels are used to denote identical or similar members. It should be understood that the drawings are merely schematic, and the dimensions and proportions of the members in the drawings are not necessarily precise.

FIG. 1 shows a top view of a circuit board mounting structure 10 according to an embodiment of the present invention.

FIG. 2 shows a top view of a printed circuit board 100 according to an embodiment of the present invention.

FIG. 3 shows a perspective view of a fixing support 200 according to an embodiment of the present invention.

FIG. 4 shows a top view of the fixing support 200 according to an embodiment of the present invention.

FIG. 5 shows a sectional drawing of the circuit board mounting structure 10 in FIG. 1 along line B-B.

FIG. 6 shows a perspective view of a first snap-fit part 130 and a second snap-fit part 250 according to a second embodiment of the present invention.

FIG. 7 shows a perspective view of the first snap-fit part 130 according to the second embodiment of the present invention.

FIG. 8 shows a perspective view of the first snap-fit part 130 and second snap-fit part 250 according to a third embodiment of the present invention.

FIG. 9 shows a top view of the first snap-fit part 130 and second snap-fit part 250 according to the third embodiment of the present invention.

FIG. 10 shows a top view of the second snap-fit part 250 according to the third embodiment of the present invention.

### DETAILED DESCRIPTION OF THE INVENTION

Embodiments of the present invention are described demonstratively below. As those skilled in the art should realize, the embodiments explained may be amended in various ways without departing from the concept of the present invention. Thus, the drawings and description are essentially illustrative, not restrictive. In the following text, identical reference numerals generally denote elements with identical or similar functions.

The present invention is described in detail below with reference to the drawings.

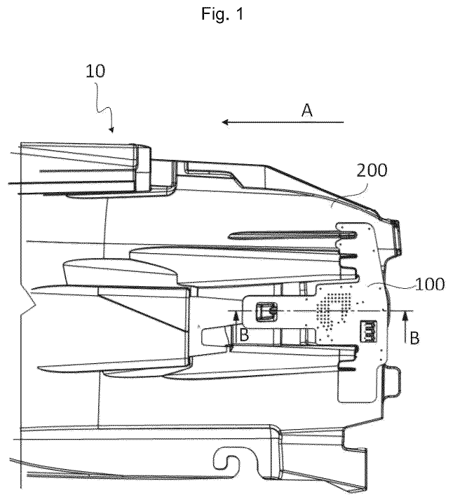

FIG. 1 shows a top view of a circuit board mounting structure 10 according to an embodiment of the present invention. As shown in the figure, the circuit board mounting structure 10 may comprise a PCB 100 and a fixing support 200 for fixing the PCB 100. Only part of the fixing support 200 is shown in the figure. It must be explained that the fixing support 200 may be of any suitable type, and may be chosen according to actual needs. As shown in FIG. 1, the PCB 100 may be clamped to the fixing support 200 in a mounting direction A, wherein the mounting direction A is substantially parallel to a board face of the PCB 100 that is used for mounting electronic components.

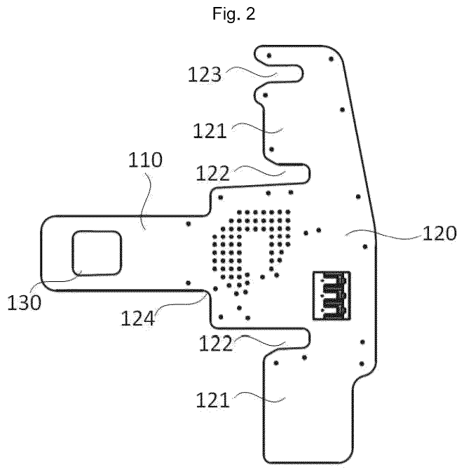

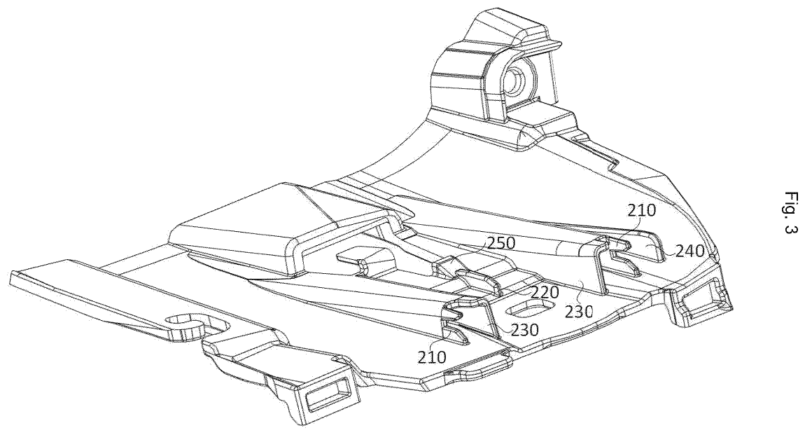

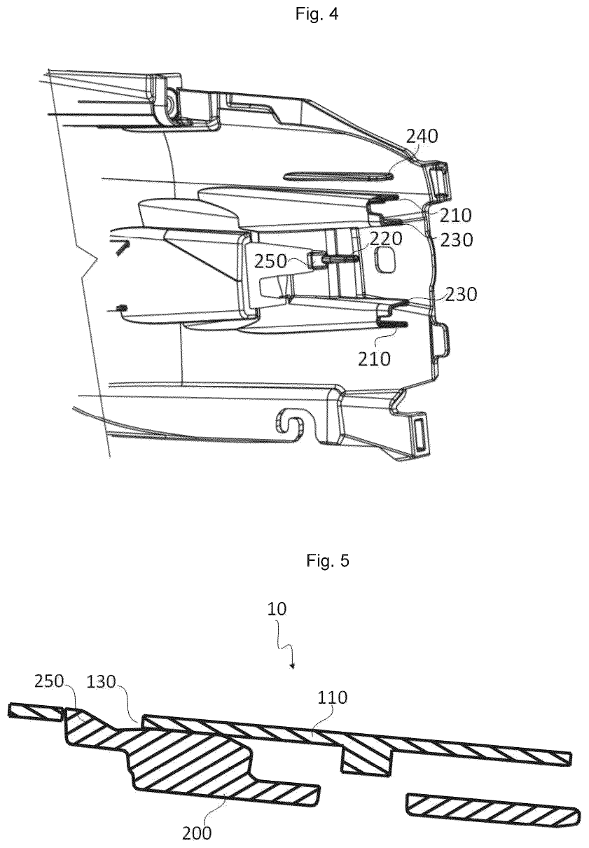

FIG. 2 shows a top view of the PCB 100 according to an embodiment of the present invention; FIG. 3 shows a perspective view of the fixing support 200 according to an embodiment of the present invention; and FIG. 4 shows a top view of the fixing support 200 according to an embodiment of the present invention. As shown in FIG. 2, the PCB 100 comprises a first part 110 and a second part 120, wherein the first part 110 can experience elastic deformation, and the resulting elastic force can press the PCB 100 tightly against the fixing support 200; this will be explained in more detail below. The second part 120 is used to carry electronic components. The first part 110 and second part 120 may be integrally formed, i.e. the PCB 100 is a single-piece PCB. As shown in FIG. 2, the first part 110 may extend substantially from a middle part of the second part 120, thereby forming a substantially T-shaped PCB 100, but the embodiments of the present invention are not limited to this; the first part 110 may also extend from another position on the second part 120. The second part 120 may comprise a part for engaging with the fixing support 200, for example but without limitation, two wing-like parts 121 arranged at two sides of the first part 110 respectively. The second part 110 may further comprise at least one guide slot, which is produced in the opposite direction to the mounting direction A of the PCB 100, and used to guide the sliding of the PCB 100 on the fixing support 200 in the mounting direction A. For example but without limitation, the at least one guide slot is two guide slots 122 arranged at two sides of the first part 110 respectively, and a guide slot 123 at the same side as one of the guide slots 122. Here, because the guide slot 123 is provided at the same side as only one guide slot 122, the guide slot 123 also has the function of preventing erroneous mounting.

As shown in FIGS. 3 and 4, the fixing support 200 comprises a part for engaging with the PCB 100, for example but without limitation, two fork-shaped parts 210 arranged to correspond to the two wing-like parts 121 of the first part 110 respectively. Preferably, the wing-like parts 121 are in a tight fit with the fork-shaped parts 210; for example but without limitation, when the wing-like parts 121 are clamped to the fork-shaped parts 210, the fork-shaped parts 210 can experience a certain degree of elastic deformation to firmly clamp the wing-like parts 121. It must be explained that the number of fork-shaped parts 210 is not limited to this, and may be chosen according to needs.

As shown in FIGS. 3 and 4, the fixing support 200 further comprises at least one guide wall, which can respectively slide in the guide slot of the first part 110 in the mounting direction A. For example but without limitation, the at least one guide wall is two guide walls 230 arranged at the sides of the two fork-shaped parts respectively, and a guide wall 240 at the same side as one of the guide walls 230, wherein the guide walls 230 can slide in the guide slots 122, and the guide wall 240 can slide in the guide slot 123.

As shown in FIGS. 3 and 4, the fixing support 200 may further comprise a guide rib 220 for causing the first part 110 of the PCB 100 to experience elastic deformation. The guide rib 220 can guide the first part 110 to slide in the mounting direction A, and supports the first part 110 in a direction transverse to the mounting direction A (for example but without limitation, the vertically upward direction in FIG. 3), such that the first part 110 experiences elastic deformation relative to the second part 120. For example, the height of the guide rib 220 may be higher than the height of the part of the fork-shaped part 210 that contacts the wing-like part 121 of the second part 120; thus, when the wing-like part 121 of the second part 120 is fixed, the first part 110 will inevitably experience elastic deformation relative to the second part 120 under the supporting action of the guide rib 220, and because the direction of the deformation is transverse to the mounting direction A and away from the fixing support 200, the resulting elastic force will clamp the PCB 100 on the fixing support 200.

When the PCB 100 and fixing support 200 are mounted, the PCB 100 slides towards the fixing support 200 in the mounting direction A. Specifically, the guide walls 230 slide in the guide slots 122, the guide wall 240 slides in the guide slot 123, the wing-like parts 121 of the second part 120 slide along the fork-shaped parts 210 and are finally clamped by the fork-shaped parts 210, and the first part 110 slides along the guide rib 220 and experiences elastic deformation under the action of the guide rib 220, to finally press the PCB 100 tightly against the fixing support 200.

In an example, because the first part 110 of the PCB 100 is a part that needs to experience elastic deformation, electronic components are preferably excluded from the first part 110, i.e. no electronic components are mounted on the first part 110, to prevent open circuits due to rupture of an electrically conductive layer when the first part 110 experiences elastic deformation.

In one example, preferably, as shown in FIG. 2, a connection region between the first part 110 and second part 120 of the PCB 100 comprises a chamfer region. This reduces the stress that arises when the first part 110 experiences elastic deformation relative to the second part 120, preventing rupture of the connection region.

It must be explained that although the second part 120 of the PCB 100 is shown as being clamped to the fork-shaped parts 210 of the fixing support 200 in the above embodiment, the manner of clamp is not limited to this. For example but without limitation, the fit between the guide walls and the guide slots is configured to be a tight fit.

In the above embodiment, because the elastic part is provided on the PCB, the elastic part being capable of experiencing elastic deformation to clamp the PCB on the fixing support, it is possible to avoid the technical problem in the prior art that injection molding is difficult when the elastic part is arranged on the fixing support, and thereby reduce production costs.

Furthermore, to increase the strength of connection between the PCB 100 and the fixing support 200, and prevent detachment of the PCB 100 from the fixing support 200, in embodiments of the present invention, the first part 110 of the PCB 100 is also snap-fitted to the fixing support 200. This is explained in detail by means of the following embodiments.

As a first embodiment, FIG. 5 shows a sectional drawing of the circuit board mounting structure 10 in FIG. 1 along line B-B. As shown in FIGS. 2-5, the first part 110 of the PCB 100 further comprises a first snap-fit part 130, and the fixing support 200 further comprises a second snap-fit part 250, arranged at a downstream side of the guide rib 220 in the mounting direction A, wherein the first snap-fit part 130 is in the form of a through-hole, and the second snap-fit part 250 is in the form of a protrusion. When the second part 120 of the PCB 100 is clamped to the fixing support 200, the through-hole can be fitted over the protrusion, at which time the through-hole can experience a certain degree of elastic deformation, and the resulting elastic force can snap the first snap-fit part 130 and second snap-fit part 250 together. Preferably, the second snap-fit part 250 may also be provided with an additional stop element as an anti-detachment part, to further prevent detachment of the first snap-fit part 130.

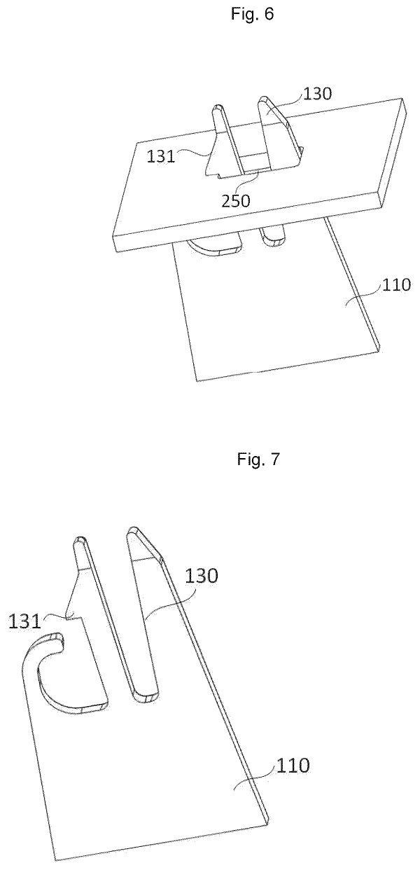

As a second embodiment, FIG. 6 shows a perspective view of the first snap-fit part 130 and second snap-fit part 250 according to the second embodiment of the present invention, and FIG. 7 shows a perspective view of the first snap-fit part 130 according to the second embodiment of the present invention, wherein, for simplicity, the second part 120 of the PCB 100 has been omitted, with only the first part 110 being shown, and most of the fixing support 200 has been omitted, with only the second snap-fit part 250 being shown. As shown in FIGS. 6 and 7, the first snap-fit part 130 is formed as a V-shaped part at an extremity of the first part 110, and the second snap-fit part 250 is in the form of a through-hole. When mounting is performed, the V-shaped part is compressed such that the distance between two branches thereof is shortened, the V-shaped part thereby slides into the through-hole, and an elastic force arising through deformation can cause the V-shaped part to tightly abut edges of the through-hole. Preferably, a stop element 131 is further provided on the V-shaped part as an anti-detachment part, to further prevent detachment of the first snap-fit part 130.

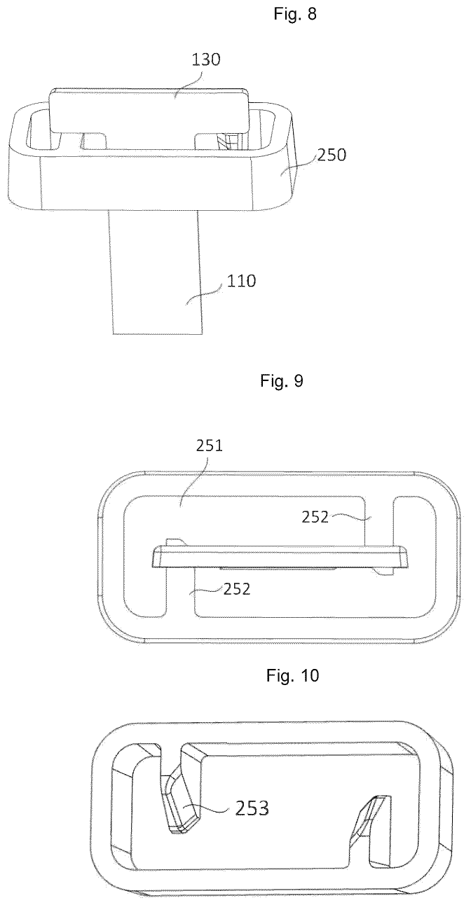

As a third embodiment, FIG. 8 shows a perspective view of the first snap-fit part 130 and second snap-fit part 250 according to the third embodiment of the present invention, FIG. 9 shows a top view of the first snap-fit part 130 and second snap-fit part 250 according to the third embodiment of the present invention, and FIG. 10 shows a top view of the second snap-fit part 250 according to the third embodiment of the present invention, wherein, for simplicity, the second part 120 of the PCB 100 has been omitted, with only the first part 110 being shown, and most of the fixing support 200 has been omitted, with only the second snap-fit part 250 being shown. As shown in FIGS. 8-10, the first snap-fit part 130 is formed as a T-shaped part at an extremity of the first part 110, and the second snap-fit part 250 comprises a through-hole 251 and two ribs 252 extending in opposite directions in the through-hole 251, wherein an inclined face 253 is formed at an extremity of each rib 252, for guiding the sliding of the T-shaped part. When mounting is performed, because the second part 120 of the PCB 100 is fixed, the T-shaped part is forcibly deformed through twisting under the guiding action of the ribs 252 to pass through the through-hole 251, and recovers from the deformation after passing through the through-hole 251. Because the size of the transverse branch of the T-shaped part is larger than the distance between the two ribs 252, the transverse branch of the T-shaped part can act as an anti-detachment part, preventing detachment of the first snap-fit part 130.

It must be explained that the form of the snap-fit connection between the first part 110 of the PCB 100 and the fixing support 200 is not limited to the above embodiments; any other suitable form of snap-fit connection may also be used.

The embodiments of the present invention further relate to a lighting apparatus comprising a circuit board mounting structure or PCB as described above. The embodiments of the present invention further relate to a motor vehicle comprising the lighting apparatus.

Although the technical objective, technical solution and technical effects of the present invention have been explained in detail above with reference to particular embodiments, it should be understood that the above embodiments are merely exemplary, not restrictive. Any amendments, equivalent substitutions or improvements made by those skilled in the art within the essential spirit and principles of the present invention shall be included in the scope of protection thereof.

What is claimed is:

1. A circuit board mounting structure, comprising a fixing support and a printed circuit board clamped to the fixing support, wherein a first part of the printed circuit board is capable of generating elastic deformation, and a resulting elastic force clamps the printed circuit board on the fixing support.

2. The circuit board mounting structure according to claim 1, wherein the printed circuit board includes a second part, the second part being clamped to the fixing support, such that the first part experiences elastic deformation relative to the second part under the action of the fixing support.

3. The circuit board mounting structure according to claim 2, wherein the fixing support includes at least one fork-shaped part, and the second part is clamped by the fork-shaped part in a mounting direction of the fixing support and the printed circuit board.

4. The circuit board mounting structure according to claim 2, wherein the fixing support includes at least one guide rib, for guiding the first part to slide in a mounting direction of the fixing support and the printed circuit board, and supporting the first part in a direction transverse to the mounting direction, such that the first part experiences elastic deformation.

5. The circuit board mounting structure according to claim 2, wherein the first part protrudes and extends from the second part, such that the printed circuit board forms a T-shaped board.

6. The circuit board mounting structure according to claim 2, wherein the second part includes at least one guide slot, and the fixing support includes at least one guide wall, the guide wall being slidable in the guide slot in the opposite direction to a mounting direction of the printed circuit board.

7. The circuit board mounting structure according to claim 2, wherein a connection region of the first part and the second part includes a chamfer region.

8. The circuit board mounting structure according to claim 2, wherein electronic components are excluded from the first part.

9. The circuit board mounting structure according to a claim 1, wherein the first part includes a first snap-fit part, and the fixing support includes a second snap-fit part, the first snap-fit part being snap-fitted to the second snap-fit part.

10. The circuit board mounting structure according to claim 9, wherein an anti-detachment part is provided on at least one of the first snap-fit part and the second snap-fit part.

11. The circuit board mounting structure according to claim 10, wherein the first snap-fit part includes a through-hole, the second snap-fit part includes a protrusion, and the through-hole is fitted over the protrusion by deformation.

12. The circuit board mounting structure according to claim 10, wherein the first snap-fit part includes a V-shaped part formed at an extremity of the first part, the second snap-fit part includes a through-hole, the V-shaped part is inserted in the through-hole by deformation, and the anti-detachment part is formed on the V-shaped part.

13. The circuit board mounting structure according to claim 10, wherein the first snap-fit part includes a T-shaped part formed at an extremity of the first part, the second snap-fit part includes a through-hole and two ribs extending in opposite directions in the through-hole, and the T-shaped part passes through the through-hole while twisting under the guiding action of the two ribs and forms the anti-detachment part.

14. A printed circuit board, capable of being clamped to a fixing support, wherein a first part of the printed circuit board can experience elastic deformation, and a resulting elastic force clamps the printed circuit board on the fixing support.

15. The printed circuit board according to claim 14, further comprising a second part, the second part being clamped to the fixing support, such that the first part experiences elastic deformation relative to the second part under the action of the fixing support.

16. The printed circuit board according to claim 15, wherein the fixing support includes at least one fork-shaped part, and the second part is clamped by the fork-shaped part in a mounting direction of the fixing support and the printed circuit board.

17. The circuit board mounting structure according to claim 15, wherein the fixing support includes at least one guide rib, for guiding the first part to slide in the mounting direction, and supporting the first part in a direction transverse to the mounting direction, such that the first part experiences elastic deformation.

18. The printed circuit board according to claim 15, wherein the first part protrudes and extends from the second part, such that the printed circuit board forms a T-shaped board.

19. The printed circuit board according to claim 15, wherein the second part includes at least one guide slot, and the fixing support includes at least one guide wall, the guide wall being slidable in the guide slot in the opposite direction to a mounting direction of the printed circuit board.

20. The printed circuit board according to claim 15, wherein a connection region of the first part and the second part comprises a chamfer region.

21.-28. (canceled)
